(19) United States
(12) Patent Application Publication
(10) Pub. No.: US 2003/0180445 A1
(43) Pub. Date: Sep. 25, 2003

(54) Method for forming a catalytic bead sensor

(75) Inventors: Chuan-Bao Wang, Oakdale, PA (US); P. Richard Warburton, Moon Township, PA (US); Beth Tomasovic, Cranberry Township, PA (US)

Correspondence Address: DENNISON, SCHULTZ & DOUGHERTY, 1745 JEFFERSON DAVIS HIGHWAY, ARLINGTON, VA, 22202, US

(73) Assignee: Industrial Scientific Corporation, Oakdale, PA

(21) Appl. No.: 10/101,960

(22) Filed: Mar. 21, 2002

(51) Int. Cl. B05D 5/12; C23C 16/00; B05D 1/36; B05D 1/08

(52) U.S. Cl. 427/58; 427/419.2; 427/248.1; 427/446

(57) ABSTRACT

A method of fabricating a catalytic bead sensor with improved stability by forming a coil of metal wire, depositing onto the coil of wire by CVD, PECVD, thermal spraying or electrophoretic deposition at least one first layer of an insulating, crack-free refractory coating, to form thereby a coil of coated wire, and depositing onto the coated wire coil at least one further layer to convert the coated wire coil to a sensing or compensating bead.

### BACKGROUND OF THE INVENTION

1. Field of the Invention

The invention relates to a method for forming a catalytic or compensating bead sensor with improved stability achieved by a structural and protective coating. The invention also relates to a catalytic bead sensor and a thermal conductivity sensor that are fabricated by vapor deposition and other deposition methods.

2. Description of Related Art

Catalytic bead combustible gas sensors have been widely used in industry to detect the presence of combustible gases and vapors for safety purposes and to provide a warning of potentially hazardous conditions before these gases and vapors reach explosive levels. A commercial catalytic bead sensor is composed of two electrically heated coil elements: a sensing element and a compensating element, which typically form two arms of a Wheatstone bridge circuit. The sensing element is formed by refractory metal oxides (e.g. alumina, silica, zirconia, thoria) doped with noble metal catalysts (e.g. palladium, platinum, rhodium) to catalyze combustion of the combustible gases. A compensating element is made from refractory metal oxides and/or glasses so that combustible gases do not burn on its surface. Since environmental parameters such as humidity and ambient temperature affect both the sensing and compensating elements, the effects of the environmental parameters on the signal output may be canceled out by use of the compensating element. The wire coils serve as two purposes: (1) to heat the sensing and compensating beads electrically to an operating temperature of ˜500° C. and (2) to detect resistance change caused by the reaction heat that is produced by the catalytic combustion of the combustible gases on the sensing bead. Combustible gas sensor are described, for example, in U.S. Pat. Nos. 3,200,011, 3,092,799, 4,313,907 and 4,416,911, and in Mosley, P. T. and Tofield, B. C., “Solid State Gas Sensors”, Adams Hilger Press, Bristol, England (1987).

The power consumption of such a combustible gas sensor is required to be low to extend battery life for battery-powered portable instruments. Power reduction down to 200 mW is achieved by employing ultra-fine Pt or alloy wires with a diameter of 7.5 to 25 μm to form the wire coils. Since the ultra-fine wires are susceptible to breakage when a portable instrument is dropped, incorporation of a glass fiber paper (U.S. Pat. No. 5,601,693) is often used to improve shock resistance.

Several fundamental problems arise in fabricating such a catalytic bead sensor:

1) It is very difficult to obtain a coil with uniform pitch and length since pitch and length are very sensitive to small changes in mechanical properties along the wire due to the difficulty in controlling the degree of annealing such a fine wire with small thermal mass. The subsequent soldering or welding steps to connect the wire coil to the external circuit often distort the coil and change its pitch and length.

2) Coating the coil by conventional methods using liquid chemicals to make sensing and compensating beads generally causes the wire coil to shrink due to chemical shrinkage induced by solvent evaporation, liquid surface tension, sintering at high temperature, and the low mechanical strength of the ultra-fine wire. The shrinkage is typically not uniform and it is found that the area with the smallest pitch shrinks more than the area with larger pitch. The non-uniform pitch leads to non-uniform temperature (i.e. hot spots) along the coil when the sensor is operated. These hot spots on the coil are detrimental to sensor stability and lifetime since the wire at the hot spots is more readily degraded due to the much higher operating temperature.

3) Degradation of the wire is, in general, a common problem for catalytic bead sensors. It is well known that platinum, a commonly used wire material, is slowly oxidized in air in the temperature range of 500-900° C. to form volatile PtO₂, resulting in degradation of the platinum wire and early failure of the gas sensor.

4) The wire, especially ultra-fine wire, is more susceptible to contamination by impurities, which can cause changes in the electrical properties of the wire. For example, most low melting point metals can alloy with platinum and therefore degrade the platinum wire. Surface contamination is a particular problem for the ultra-fine wire since the impurity may contaminate the entire thickness of the wire and radically alter its resistance, whereas the impurity may only diffuse to a depth of a few microns and be unnoticed on a thick wire.

5) The ultra-fine wire is more susceptible to reducing gases such as pure methane and hydrogen. When a catalytic bead sensor is exposed to a high-concentration reducing gas, the reducing gas interacts with the wire and changes the wire surface structure and electrical properties.

In the prior art, an insulating refractory material generally has been applied in a liquid form to the wire to produce a dense sheath around the coil, and then a catalytic material is further applied to form the sensing bead, as described in U.S. Pat. Nos. 3,959,764, 4,068,021, and 4,560,585. Nevertheless, this conventional method substantially shrinks the coil and causes the hot-spot problem, especially for coils made from ultra-fine wire. Also, cracking of the coating layer is not avoidable during the drying step where solvent evaporation induces coating shrinkage and cracking. A coating with cracks cannot effectively protect the wire from corrosion and contamination.

U.S. Pat. No. 4,296,399 discloses a method for fabricating a catalytic bead sensor by winding a coil around a molybdenum mandrel and coating the coil with a binder. The binder is cured to retain the coil and the mandrel is then removed by chemical etching. Subsequently, a catalyst is applied to form a sensing bead. While this method might prevent coil shrinkage and coating cracking, the process is complicated and costly.

Therefore, it would be desirable to have a method for forming a structural and protective coating around the wire coil without cracking and shrinking the coil (1) to minimize hot-spots, (2) to protect the wire coil from degradation, (3) to protect the wire coil from contamination by impurities, (4) to reduce the influence of reducing gases, and (5) to stabilize the dimension of the wire coil. It would be further desirable to have a fully automated fabrication process for manufacturing a catalytic bead sensor and a thermal conductivity sensor.

Chemical vapor deposition (CVD) and plasma-enhanced chemical vapor deposition (PECVD) are coating processes in which a solid material is deposited from a vapor precursor or precursors by a chemical reaction occurring on or in the vicinity of a normally heated substrate surface. These processes are widely used in industry to make thin films serving as dielectrics, conductors, passivation layers, oxidation barriers, epitaxial layers, and wear-, corrosion-, and heat-resistant coatings. The principles and applications of such methods are discussed, for example, in Pierson, H. O., Handbook of Chemical Vapor Deposition: Principles, Technology, and Applications (Second Edition), Noyes Publications, Park Ridge, N. J., USA (1999).

It is known that the CVD or PECVD method can be used to coat electric wires. For example, Japanese Patent No. 09-204832 discloses a method for manufacturing an electric wire by plasma CVD of a silane derivative on an enamel-coated wire at a temperature less than 200° C. The wire made by this method has no pinholes and good flexibility. Japanese Patent No. 09-246377 discloses a process and apparatus for plasma CVD of an insulating film on a metal wire in the manufacture of semiconductor devices.

CVD has been used in the process of fabricating semiconductor or catalytic gas sensors. For example, U.S. Pat. No. 4,504,522 discloses a method for making a titanium dioxide resistive film on an insulating substrate by CVD, which can be used as an oxygen sensing element. PCT application WO 00/43772 discloses a hydrogen sensor, which includes a thin film sensor element formed by metal-organic chemical vapor deposition (MOCVD) or physical vapor deposition (PCV) on a micro-machined hotplate. U.S. Pat. No. 5,820,922 discloses a micro-machined thin film catalytic sensor made by CVD from the precursor Pt(acac)₂ onto hot microfilaments. U.S. Pat. No. 5,401,470 discloses a method for making a compensating element for use in a catalytic bead sensor by exposing a sensing element to a gas phase catalytic poison such as hexamethyldisiloxane completely to destroy its catalytic ability. Examples of these types of sensors are also described in Debeda et al, “Sensors and Actuators B”, 26-27, 297-300 (1995); and Zanini et al,“Sensors and Actuators A”, 48, 187-192 (1995).

Thermal spraying processes form a continuous coating by melting the consumable material into droplets and causing these droplets to impinge on a substrate. Thermal spraying processes include flame spraying, plasma arc spraying, electric arc spraying, detonation gun and high-velocity oxy/fuel. Thermal spraying usually yields coatings with almost certain porosity and is thus appropriate for building porous catalytic materials in catalytic bead sensors.

In electrophoretic deposition, a voltage is applied between a substrate and a counter electrode immersed in a colloidal suspension. The charged colloidal particles move toward the substrate where they discharge and deposit under the electrostatic potential. This method was used to coat ceramic on platinum wire as described in Miyazaki et al, Journal of the Ceramic Society of Japan, 106(11), 1129-34 (1998).

### SUMMARY OF THE INVENTION

An object of the invention is to provide a combustible gas sensor of the catalytic bead type that has improved stability.

Another object of the invention is to provide a combustible gas sensor of the catalytic bead type that has a protective and structural coating layer around the coils of the sensing and compensating beads.

A further object of the invention is to provide a substantially crack-free coating to protect wire from degradation and contamination.

A still further object of the invention is to provide a coating that does not shrink the coils to any significant extent to serve as a structural coating for stabilizing the coil dimension.

To achieve these and other objects, the invention is directed to the use of chemical vapor deposition (CVD), plasma-enhanced chemical vapor deposition (PECVD), thermal spraying deposition, or electrophoretic deposition to coat a coil of wire used to form a catalytic or compensating bead. The process is used to form at least a thin (1-10μ), crack-free layer on the coil of wire, and preferably to form a thicker (20-100μ) layer which dimensionally stabilizes the coil by connecting the turns of wire together.

In a further embodiment, a combustible gas sensor of a catalytic bead type is fabricated by CVD, PECVD, thermal spraying deposition, or electrophoretic deposition, which can be used as part of a fully automated bead fabrication process.

In a still further embodiment, a gas sensor of the thermal conductivity type is fabricated utilizing a bead formed by CVD, PECVD, thermal spraying deposition, or electrophoretic deposition.

According to the invention, a dense protective coating layer around the wire of the coil is deposited by CVD, PECVD, thermal spraying deposition, or electrophoretic deposition without cracking. The coating material is selected from the group consisting of refractory oxides, carbides, nitrides (e.g. silica, alumina, titania, zirconia, aluminum carbide, silicon nitride) and mixtures thereof.

This dense, protective coating that does not have cracks seals the wire inside a dense refractory coating that is resistant to corrosive agents, oxidizing gases, reducing gases, and metal impurities that would otherwise readily access the wire through cracks to cause wire degradation.

According to the invention, a further layer is deposited, in the form of a structural coating layer around the coil. This layer is also deposited by CVD, PECVD, thermal spraying deposition, or electrophoretic deposition without shrinking the coil. The coating material is also selected from refractory oxides, carbides, or nitrides (e.g. silica, alumina, titania, zirconia, aluminum carbide, silicon nitride). While conventional liquid coating methods generally cause significant shrinkage of the coil, leading to hot spots, CVD, PECVD, thermal spraying deposition and electrophoretic deposition coating do not shrink the coil so that the original shape of the coil is retained and the hot spots are minimized.

According to the invention, a one-step or multi-step CVD, PECVD, thermal spraying deposition, or electrophoretic deposition is used to form one layer or multi-layers. For example, a two-step process may be used first to form a very dense thin layer on the wire surface of the coil and then to form a relatively loose thick layer to connect the coil pitches together and to sheathe the coil. The inside dense layer effectively blocks access of corrosive agents, oxidizing gases, reducing gases, and impurities to the wire, and escape of platinum oxide vapor from the wire surface, and thus effectively protects the wire from oxidation, reduction, thermal etching, and alloying with other metals. The outside thick layer serves as a structural coating to maintain the coil spacing and stabilize the coil dimension.

According to the invention, sensing and compensating beads are fabricated from wires coated in the above manner. In a first embodiment, conventional methods are used, for example, application of a solution or slurry to the coated wire. The final catalytic and compensating beads may contain layers of different chemical compositions.

Alternatively, sensing and compensating beads can be fabricated further by CVD, PECVD, thermal spraying deposition, or electrophoretic deposition. Compared to the conventional methods, CVD, PECVD, thermal spraying deposition and electrophoretic deposition provide advantages for fabricating sensing and compensating beads in that they enable full automation of bead fabrication, and thereby enable large-scale production with high performance at low cost.

According to the invention, a thermal conductivity sensor can be fabricated by CVD, PECVD, thermal spraying deposition, or electrophoretic deposition.

### BRIEF DESCRIPTION OF THE DRAWINGS

FIG. 1 is a schematic diagram of a prior art catalytic bead sensor;

FIG. 2 is a schematic diagram of a prior art Wheatstone bridge circuit in which sensing and compensating elements are connected;

FIG. 3 is a schematic diagram of chemical vapor deposition apparatus for coating and sheathing wire coils;

FIG. 4 is a photomicrograph of an uncoated wire coil for a catalytic bead sensor;

FIG. 5 is a photomicrograph of a wire coil after having been coated with a thin and dense refractory material by CVD;

FIG. 6 is a photomicrograph of a wire coil after further coating by CVD;

FIG. 7 is a photomicrograph of a wire coil after having been partially sheathed by CVD;

FIG. 8 is a photomicrograph of a wire coil after having been completely sheathed by CVD;

FIG. 9 is an enlarged cross-sectional view of the wire coil in FIG. 8, which has been completely sheathed by CVD;

FIG. 10 is an enlarged cross-sectional view of a sensing element made from the coated and sheathed coil of FIG. 8;

FIG. 11 is an enlarged cross-sectional view of a hollow sensing element made from the coated and sheathed coil of FIG. 8;

FIG. 12 is a schematic diagram of a CVD apparatus with three chambers for formation of insulating, metal oxide support, and catalyst coatings for fabrication of sensing beads;

FIG. 13 is a photomicrograph of a sensing element made by CVD; and

FIG. 14 is a graph of bridge output vs. elapsed time for a sensor made from the sensing element of FIG. 13 during repeated exposures to zero air and another gas mixture (2.5% methane/air, 0.35% pentane/air, 0.63% acetylene/air, and 0.65% acetone/air).

### DESCRIPTION OF THE PREFERRED EMBODIMENT

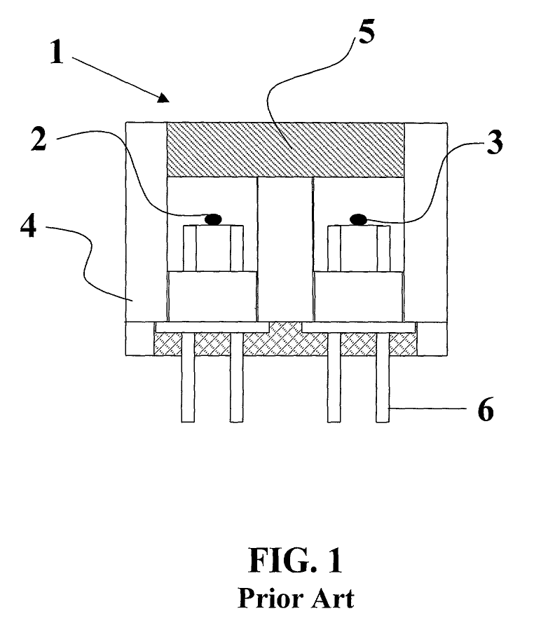

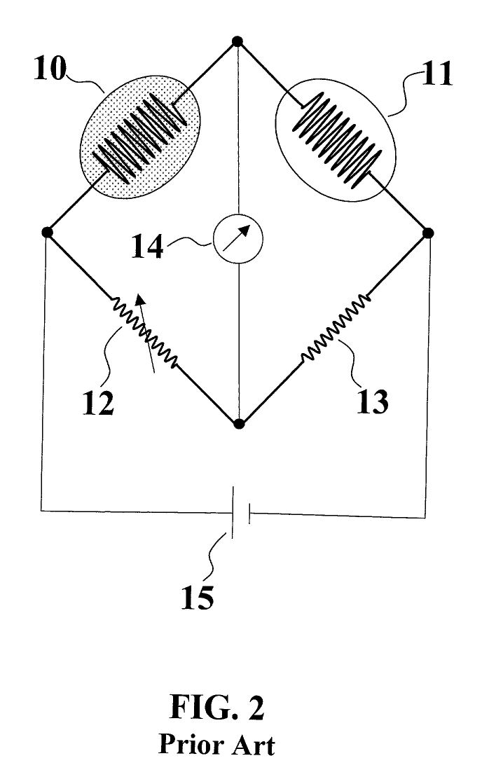

FIG. 1 illustrates a typical catalytic bead sensor 1, which comprises a sensing element 2 and a compensating element 3. Both the sensing element 2 and the compensating element 3 are enclosed within a housing 4. The gas mixture to be tested enters into the housing 4 by diffusion through a porous sintered material 5, and contacts both sensing element 2 and compensating element 3. Sensing element 2 and compensating element 3 are mounted on posts 6 which serve as electrical connectors to a circuit such as that shown in FIG. 2.

FIG. 2 illustrates the working principle of a catalytic bead combustible gas sensor, where a sensing element 10 is connected into one arm of a Wheatstone bridge circuit and a compensating element 11 is connected into an adjacent arm. The other arms are constituted by a variable resistor 12 and a fixed resistor 13 having a value such that the bridge can be balanced by adjustment of resistor 12. Across the two diagonals of the bridge are connected a voltmeter 14 and a voltage source 15. The output voltage of the source 15 is chosen so as to heat the sensing element 10 and the compensating element 11 to a desired operating temperature, usually 400-650° C., at which temperature combustible gases will undergo catalytic oxidation. The variable resistor 12 is adjusted so that the voltmeter 14 indicates a zero reading when the sensing element 10 and the compensating element 11 are exposed to an atmosphere without combustible gases or vapors. The voltmeter 14 is calibrated by exposing the sensing element 10 and the compensating element 11 to a known combustible gas concentration and then to the atmosphere that is required to be monitored. Any combustible gas present in the atmosphere will catalytically oxidize on the surface of the sensing element 10 but not on the surface of the compensating element 11, causing the temperature of the sensing element 10 to rise with a consequent change in its resistance. This increase in resistance causes a change in the potential across the voltmeter 14, which then provides a measure of combustible gas concentration in the atmosphere.

The gas sensor may also utilize other circuits known in the prior art, including other forms of Wheatstone bridge circuits, constant power circuits, constant current circuits, varied power circuits, pulse power circuits, the Anderson loop (described in Anderson, K. F., ISA-Tech 97, Anaheim, CAlif., October 1997), circuits which operate the sensing and compensating elements at different power, and single bead circuits, in which temperature and/or humidity sensors may be used to compensate for the environmental temperature and humidity effects.

The wire used for the sensing and compensating element has a diameter in the range of 7.5 to 50 μm and may be formed from platinum and its alloys, or selected other metals and alloys. The wire is wound into a helical coil with a diameter in the range of 0.005 to 0.030 inch (0.127-0.762 mm), and a length in the range of 0.008 to 0.100 inches (0.203-2.54 mm), and preferably 0.012 to 0.018 inches (0.305-0.457 mm). The coil is then connected to a two-pin electric header or a track carrying substrate (as disclosed in U.S. Pat. No. 5,601,693) by soldering, welding, pasting, or other wire bonding method.

In the following description, the CVD or PECVD process is used as an example to illustrate the invention. It is understood that the descriptions here are applicable to the other coating methods of the invention.

According to the invention, the refractory materials are deposited by CVD or PECVD from precursors of either inorganic compounds (e.g. silicon hydrides, silicon tetrachloride, dichlorosilane, methyl trichlorosilane, silicon tetrafluoride, aluminum chloride, aluminum bromide, titanium chloride, zirconium chloride, and zirconium bromide) or organic compounds (e.g. hexamethyldisiloxane, tetramethoxysilane, tetraethoxysilane, diacetoxyditertiarybutoxy silane, octamethyl-cyclotetrasiloxane, tris(2,2,6,6-tetramethyl-3,5-heptanedionato) aluminum, aluminum isopropoxide, trimethyl aluminum, triethyl aluminum, tetraisopropyl titarate, tetrakis-diethylamino titanium, tetrakis-dimethylamino titanium, zirconium tetramethyl heptadionate, bis(cyclopentadienyl)zirconium, zirconium (IV) trifluoroacetylacetonate, and zirconium ethoxide) through decomposition, oxidation, hydrolysis, nitridation, or carbidization reactions.

The choice of a refractory precursor depends on the following practical considerations: (1) it should be sufficiently volatile to exert an appreciable vapor pressure at relatively low temperature, (2) it should evaporate at low temperature or otherwise not decompose excessively when heated, (3) it should form a desired refractory material easily on the heated coils at a temperature not higher than 1500° C., and (4) it should be relatively safe to handle without excessive toxicity, flammability, and corrosion problems.

Depending on the individual CVD or PECVD reaction, some other gaseous reactants may be introduced into the CVD or PECVD reactor together with one of the above-mentioned precursors. For example, an oxidizing agent such as oxygen, ozone, carbon dioxide, hydrogen peroxide, or nitrous oxide may be combined with a precursor to produce an oxide refractory material. In CVD or PECVD reactions for the deposition of nitrides, ammonia or nitrogen is typically used as a source of nitrogen. In the CVD or PECVD process for formation of carbides, hydrocarbons such as methane, ethane, propane, propene, or toluene are commonly used as a source of carbon to react with a precursor to produce a carbide refractory material. For the CVD or PECVD deposition through a decomposition reaction of a precursor, an inert gas is typically used as a carrier during the deposition process.

The temperature at which the deposition process occurs depends on the type of process being carried out. Thus, electrophoretic deposition takes place at the lowest temperature, generally about 0-100° C., with PECVD taking place at about 200-800° C., CVD taking place at about 500-1200° C. and thermal spraying taking place at about 200-1200° C.

According to the invention, where a one-step CVD or PECVD deposition process is applicable, it is preferred to use a multi-step CVD or PECVD deposition process. For example, a two-step CVD or PECVD deposition is used first to form a very dense thin layer on the wire surface of the coils and then to form a relative loose thick layer to connect the coil pitches together and to sheathe the coils.

According to the invention, it is preferred that the first thin dense refractory layer is made of an oxide, carbide, or nitride that has a coefficient of linear thermal expansion close to that of the wire, and the second thick refractory layer is made of an oxide, nitride, or carbide that has a fast deposition rate so that the coating layer can grow fast enough to sheathe all turns of a coil. For example, the first thin dense refractory can be alumina and the second thick refractory layer can be silica.

The deposition rate, microstructure and surface morphology of CVD or PECVD can be controlled and tailored by varying parameters that are often interrelated, including precursor, substrate, temperature, pressure, supersaturation, impurities, temperature gradients, and gas flow. These parameters need to be controlled to produce a repeatable coating.

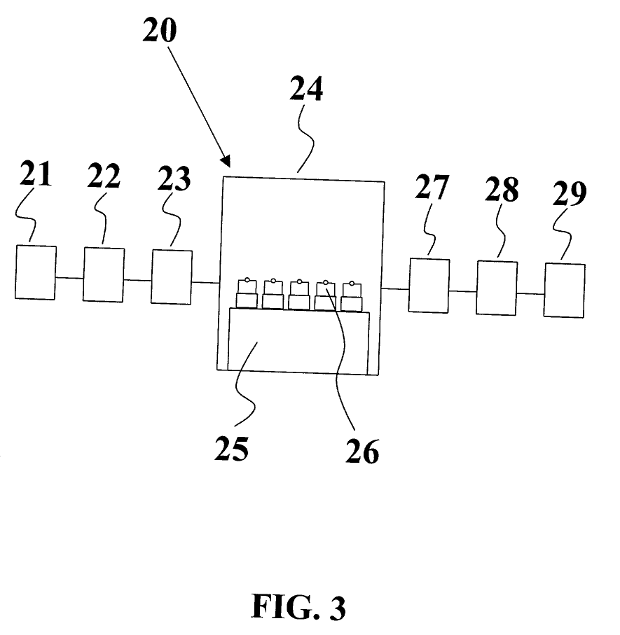

FIG. 3 shows a vaporization CVD system, where a dilution gas is supplied by a gas cylinder 21, regulated by a flowmeter 22, and flows through a liquid evaporator 23 to bring a precursor into reactor zone 24. The helical coils 26, are heated electrically and controlled by a control circuit 25. The total pressure in the reactor 24 is regulated and controlled by a pressure control system 27 and a vacuum pump 28. A scrubber 29 is used to remove the potentially hazardous substances used in a CVD process.

The CVD system can be varied to meet the needs of a specific process. For example, several reactor chambers may be included with individual controls of gaseous compositions and pressure. There may be more than one reactant introduced into the reactor region at the same time or in a sequence. For example, both silicon hydride and ammonia are introduced into the reactor for formation of silicon carbide coating. The precursor compound may be introduced into the CVD or PECVD reactor through evaporation, sublimation, or dilution with a cylinder gas.

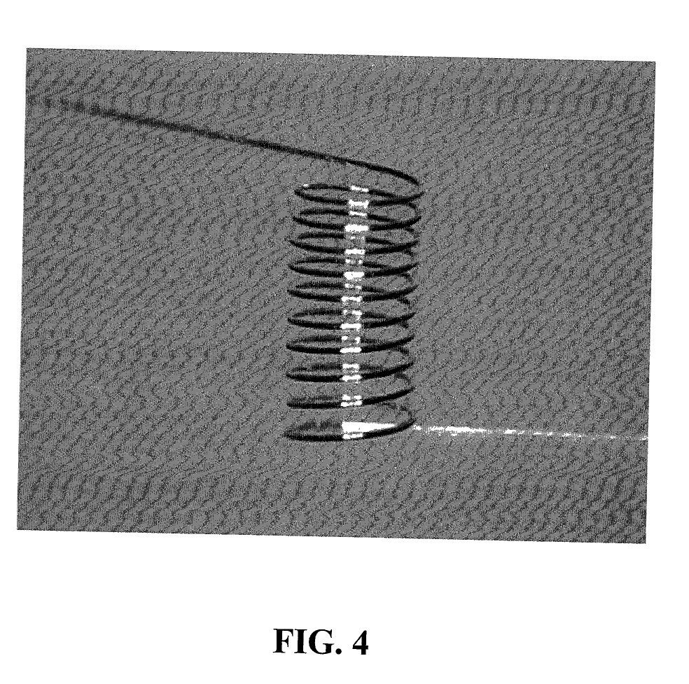

FIG. 4 is a photomicrograph of an uncoated wire coil for a catalytic bead sensor according to the invention, which is made of an ultra-fine wire of a conductive material such as platinum. It can be seen that the pitch of the coil is not uniform, especially at the bottom. The location of the varied pitch can be anywhere along the coil due to the non-uniformity of the mechanical properties of the wire.

Prior to the CVD or PECVD coating, the wire coils are heated to a temperature of 100-1200° C. (preferably 500-800° C.) to clean the wire surface of the coils in vacuum or a carrier gas of 0-25% oxygen in argon, nitrogen, or other suitable inert gas compositions. This cleaning procedure may be omitted if the coil surface is clean initially, or has been cleaned by other methods.

Before introducing a precursor and other reactants, the experimental conditions such as coil temperature and pressure are adjusted to favor the formation of a dense refractory coating around the wire of the coil. Then, the gaseous precursor and other reactants are introduced into the reactor to contact with the coils by sublimation, evaporation, or a flow of a carrier gas.

For deposition of refractory oxides, the presence and concentration of oxygen, ozone, or other oxidants in the carrier gas significantly affects the microstructure of the coating layer and thus the coating quality. It is preferred to have oxygen or ozone in the carrier gas to assist the decomposition and oxidation of the coating precursor.

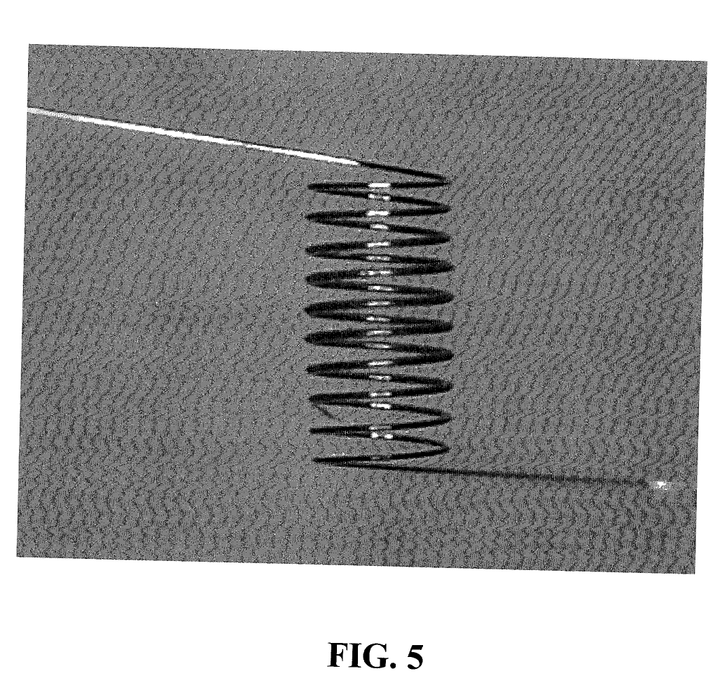

FIG. 5 is a photomicrograph of a wire coil after having been coated with a thin dense refractory layer by CVD or PECVD. It can be clearly seen that the middle turns of the coil have larger sizes than the end turns since the coating formed faster at the hotter middle area. If the pitch is uniform, the coating will start in the middle part of the coil where the highest temperature exists; if the pitch is not uniform, the coating may start at a crowded area of the coil (i.e. the area where turns are spaced close together). The thin dense refractory layer is allowed to build up to a thickness in a range of 1-25 μm and serves as a degradation barrier to prevent noble metal wires from being oxidized and vaporized, an insulator to prevent electric shorting due to touching turns or reduced catalysts that are in a metallic state, and a corrosion resistant barrier to prevent the coils from being attacked by external chemicals such as metals, halides, sulfides, and reducing gases.

Subsequently, the experimental conditions are adjusted to grow a thick relatively loose coating to connect the turns of the coils together. The composition of this second coating may differ from the first dense refractory coating.

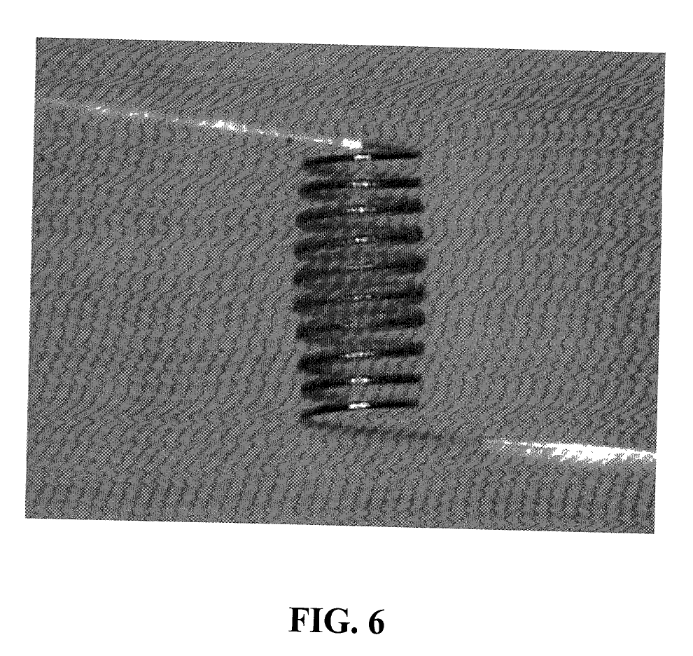

FIG. 6 is a photomicrograph of a wire coil after having been further coated with a thick refractory layer by CVD or PECVD. The further growth of the thick refractory layer results in the connection of a few turns of the coil.

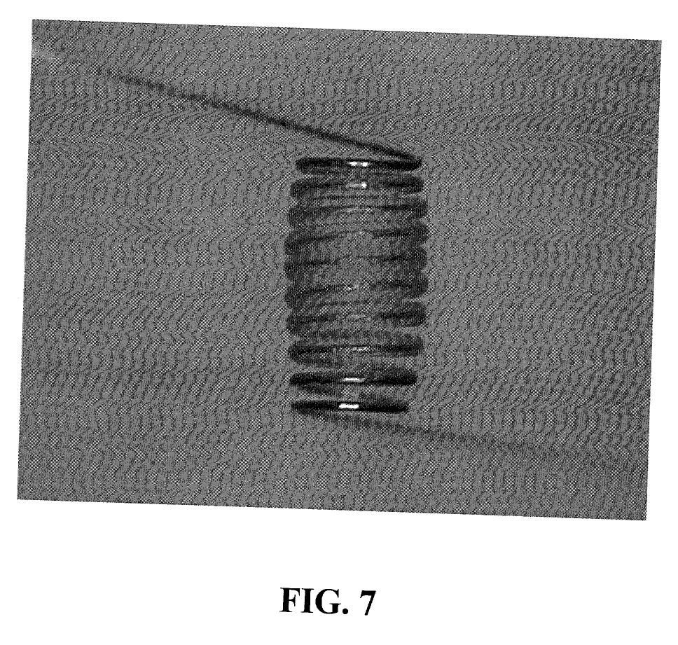

FIG. 7 shows that the several middle turns of a coil have been connected and sheathed by further exposure to the reaction gases.

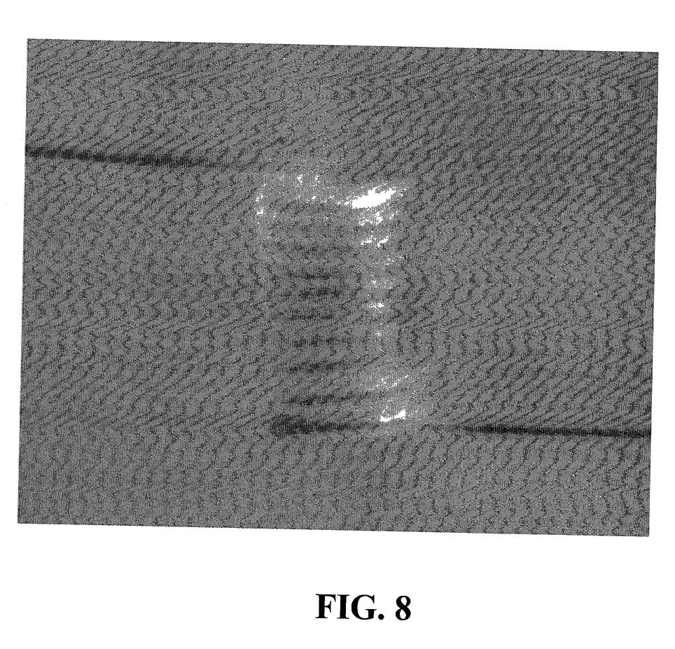

FIG. 8 shows that all the turns of the wire coil have been completely connected by the further grown thick coating. This thick coating primarily serves as a structural support to hold the turns of the coil together without shrinkage of the coil and thus stabilizes the coil dimensions.

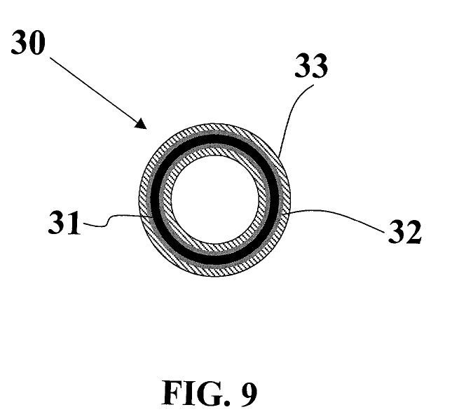

FIG. 9 is an enlarged cross-sectional view of the wire coil in FIG. 8, which has been completely sheathed by the refractory material. The coated and sheathed coil 30 comprises platinum wire 31, a dense refractory coating layer 32 with a thickness of about 5 μm, and a thick refractory sheathe 33 with a thickness of about 10 μm.

In the above example, the first layer 32 and the second layer 33 differ from each other in structure and properties such as density, micro-morphology, and compositions. However, according to the invention, the structural and protective coating may comprise more than two layers with different structures and compositions, or only one single layer with a uniform structure and composition through the whole coating, or any other combination.

After being coated, the wire coils may be further heated to a temperature between 800-1500° C. in a desired gas stream. The purpose of this post-treatment is to further stabilize the coating materials and/or to convert the coating materials to desired compositions, structures and properties.

Based on the coated coil in FIG. 8, a sensing bead is fabricated by a conventional method using a slurry containing a porous metal oxide catalyst support powder (e.g. alumina, silica, zirconia, and/or cerium-, lanthanum-, yttrium-stabilized zirconia, or other porous metal oxides) and a catalyst precursor (e.g. salts of noble metals such as platinum, palladium, and rhodium, or other transition metals), as described in U.S. Pat. Nos. 3,200,011, 3,092,799, 4,313,907, and 4,416,911. Upon heating by passing a current through the coil, the catalyst precursor is decomposed into a noble metal oxide and/or metal, which is finely dispersed on the porous oxide support surface. The sensing bead may be formed by applying multiple coatings. Many other methods for the formation of the sensing element in a catalytic bead sensor by using a solution or slurry are well known in the prior art, and these alternate methods can readily be employed in place of the description herein.

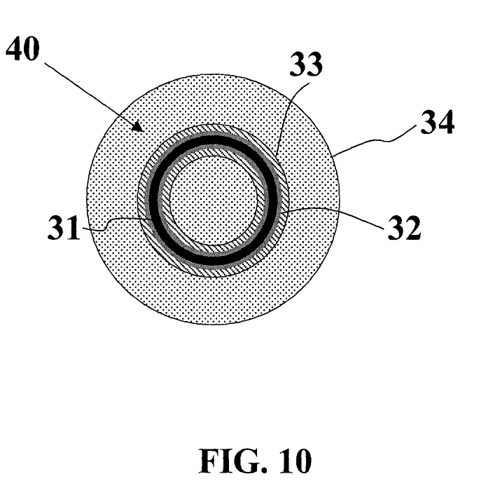

FIG. 10 is an enlarged cross-sectional view of a sensing bead made from the coated coil in FIG. 8, in which the sensing bead 40 is built up by an oxide-supported catalyst 34.

The poison resistance of the sensing element can be further improved by the method described by the inventors in U.S. patent application Ser. No. 09/771,882, filed on Jan. 30, 2001, entitled “Poison Resistant Combustible Gas Sensors and Method for Warning of Poisoning”.

Based on the coated coil in FIG. 8, a compensating bead is then fabricated by a conventional method such as applying a solution containing aluminum nitrate, or a slurry containing an alumina powder and a binder. The catalytic activity of alumina is inhibited by treatment with a solution of an alkali or alkaline-earth compound (e.g. potassium hydroxide), or by sealing with a glass layer. Many other refractory metal oxides and doping materials can also be used to form a compensating bead. The methods for fabricating a compensating element are described in many patents such as U.S. Pat. Nos. 4,332,772 and 4,447,397. A compensating element may also be fabricated by depositing at least one catalyst poison such as silica by CVD or PECVD to inhibit the catalytic activity of the sensing element described in U.S. Pat. No. 5,401,470.

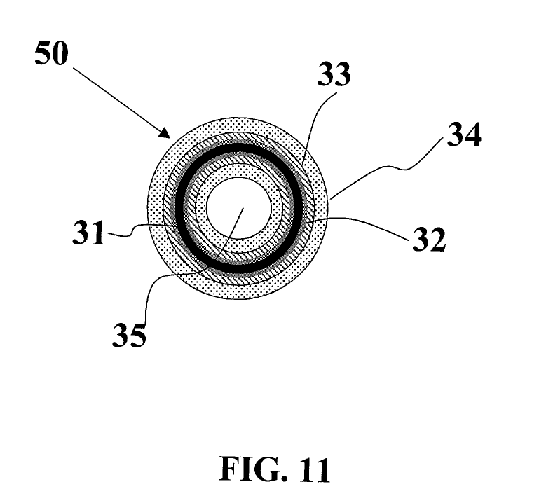

The sensing and compensating elements may be hollow to further lower mass and power consumption. As shown in FIG. 11, a sensing element 50 is made such that a catalytic bead is hollow in its interior, and a compensating element may be fabricated in the same manner.

Therefore, in one preferred embodiment of this invention, a catalytic bead sensor is fabricated by a process including the steps of:

coating a helical wire coil with a dense, thin refractory layer first, followed by a relatively loose thick refractory layer to sheathe the whole coil by CVD, PECVD, thermal spraying deposition, or electrophoretic deposition; and

fabricating a sensing bead from the coated coil by a conventional method such as applying an aqueous or non-aqueous slurry containing a porous metal oxide powder that serves as catalyst support and a catalyst precursor; or

fabricating a compensating bead from the coated coil by a conventional method.

In a second embodiment of the invention, a catalytic bead sensor is fabricated by using the steps of:

coating a helical wire coil with a dense, thin refractory layer first, followed by a relatively loose thick refractory layer to sheathe the whole coil by CVD, PECVD, thermal spraying deposition, or electrophoretic deposition; and

fabricating a sensing bead from the coated coil by further depositing a porous metal oxide support (e.g. alumina, silica, zirconia, and/or cerium-, lanthanum-, or yttrium-stabilized zirconia) by CVD, PECVD, thermal spraying deposition, or electrophoretic deposition, and followed by applying an aqueous or non-aqueous solution containing a catalyst precursor (e.g. palladium chloride, hexachloroplatinic acid, and/or rhodium chloride); or

fabricating a compensating bead, if desired, from the coated coil by further depositing a metal oxide support (e.g. alumina, silica, or their combinations) by CVD, PECVD, thermal spraying deposition, or electrophoretic deposition, followed by applying a alkaline or alkaline-earth compounds (i.e. potassium hydroxide) solution or glass.

In a third embodiment of the invention, a catalytic bead sensor is fabricated by a process including the steps of:

coating a helical wire coil with a dense, thin refractory layer first, followed by a loose thick refractory layer to sheathe the whole coil by CVD, PECVD, thermal spraying deposition, or electrophoretic deposition; and

fabricating a sensing bead from the coated coil by further depositing both a porous metal oxide support (e.g. alumina, silica, zirconia, and/or cerium-, lanthanum-, or yttrium-stabilized zirconia) and a catalyst (e.g. platinum, rhodium, and/or palladium) by CVD, PECVD, thermal spraying deposition, or electrophoretic deposition; or

fabricating a compensating bead from the coated coil by further depositing both a metal oxide support (e.g. alumina, titania, silica, or their combinations) and a non-active material (e.g. silica, glass) by CVD, PECVD, thermal spraying deposition, or electrophoretic deposition, the non-active material being one which does not catalytically combust combustible gases and thus prevents the compensating bead from burning combustible gases.

The object of the third embodiment is to fabricate a catalytic bead sensor solely by a CVD, PECVD, thermal spraying deposition, or electrophoretic deposition method. Compared to the conventional method, the CVD, PECVD, thermal spraying deposition, or electrophoretic deposition method provide advantages in that they are readily amenable to fully automated bead fabrication process by combining coating coils, fabricating sensing beads, and fabricating compensating beads into an integrated one- or multiple-step process, they are feasible for large-scale production with high quality at low costs, and they are suitable for manufacturing catalytic bead sensors where ultra-fine wires are used and handled with extreme difficulties.

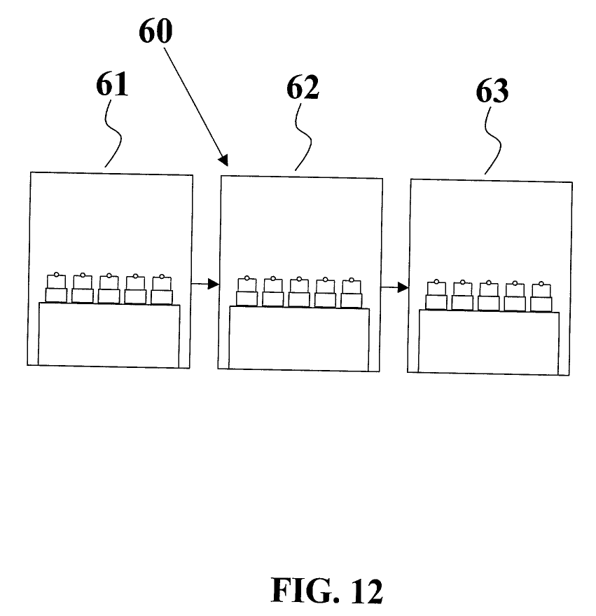

The CVD, PECVD, thermal spraying deposition, or electrophoretic deposition reactor and manufacturing process can take many different forms such as a multi-stage reactor or a one-stage reactor with precursor gases applied in sequence. An example of a multi-stage CVD or PECVD system 60 containing three reactor chambers 61, 62, and 63 is shown in FIG. 12. In the reactor chamber 61, the wire coils are coated and sheathed with refractory materials as described previously. In the reactor chamber 62, the coated coils are further deposited with a porous metal oxide as a catalyst support material from a gaseous compound. In the reactor chamber 63, a noble metal catalyst is deposited onto the surface of the porous metal oxide support to form a sensing element from a noble metal precursor.

In the reactor chamber 62, the experimental conditions are adjusted to favor the formation of a porous metal oxide (e.g. alumina, silica, zirconia, cerium-, lanthanum-, yttrium-stabilized zirconia, or a combination) with a high surface area. The microstructure and surface morphology of the metal oxide by CVD or PECVD are tailored by controlling temperature, pressure, supersaturation, deposition rate, impurities, and gas flows.

In the reactor chamber 63, an organic compound containing a noble metal element is brought into the chamber to facilitate the dispersion of a catalyst on the surface of the metal oxide support. The organic compounds which may be used include platinum acetylacetonate, platinum dicarbonyl dichloride, platinum hexafluoro-2,4-pentadionate, platinum tetrakis-trifluorophosphine, tris(dibenzylideneacetone)dipalladium, palladium acetate, rhodium acetyl acetonate, rhodium trifluoro-acetyl acetonate and rhodium carbonyl, and many other suitable compounds are available as well.

The catalyst and its support material may also be built up by a one-step process, where the catalyst precursor and the support precursor vapors are introduced at the same time, or a special precursor containing both the catalyst and support elements is used. The special precursor could be for example, platinum (0)-1,3-1,1,3,3-tetramethyldisiloxane complex or platinum(0)-2,4,6,8-tetramethyl-2,4,6,8 tetravinyl-cyclotetrasiloxane complex.

A compensating element is built up by depositing silica from an inorganic or organic compound until a certain size, or by depositing other refractory materials (e.g. alumina, titania, zirconia) first and then silica. It is well known that silica is not active for catalyzing combustion of combustible gases or vapors, and therefore it is an ideal material for building up compensating beads. However, any other inert refractory material or combinations of refractory materials can also be used to build a compensating element.

The invention is directed to structural and protective coatings without shrinkage or cracking, and can be applied to thermal conductivity sensors and other types of catalytic sensors where the electric heater is a thick film, thin film, ribbon, or other shapes or structures. For planar heaters such as films, physical vapor deposition (PVD) may also be applicable although its deposition rate is typically low. PVD is not suitable for wire helical coils since deposition from PVD only occurs on the substrate that is directly toward the deposition source.

Gas sensors of the thermal conductivity type are well-known in the prior art and are disclosed, for example, in U.S. Pat. Nos. 4,813,267 and 5,535,614, Japanese Patent Kokai Publication Nos. 55-7698 and 57-16343, and Japanese Patent Kokoku Publication No. 5-18055. Traditional thermal conductivity sensors are divided into two types: Type I is typically used in gas chromatographs and Type II is used in portable gas detectors.

The Type I thermal conductivity gas sensors comprise a pair of electrically-heated elements such as platinum wires or thermistors, which are identical in size, structure, and thermal properties, each element containing a chamber serving as a heat sink. The elements are electrically heated in a Wheatstone bridge circuit, and during use, the sensing element is brought into contact with a gas mixture to be tested and the compensating element is in contact with a reference gas such as helium, argon, or nitrogen. The temperature of the compensating element will be constant since it contacts a reference gas with a known thermal conductivity. The temperature of the sensing element depends on the composition of the gas mixture being tested. The ratio of a particular gas in a two-gas mixture is then determined according to the output voltage difference in the Wheatstone bridge.

Type II thermal conductivity gas sensors are similar in design and construction to Type I sensors except that the compensating element is sealed inside a container such as a glass tube with a reference gas, for environmental temperature compensation. The gas mixture to be tested diffuses into the sensing element and causes a temperature change. A particular gas concentration is determined based on the difference in the output voltage in the Wheatstone bridge circuit. Since the compensating element is sealed inside a container, this type of thermal conductivity sensor cannot compensate for the environmental humidity effect, and a false reading may arise when a gas detection instrument containing this sensor is exposed to a highly humid gaseous environment.

In the fourth embodiment, the invention is directed to fabrication of a thermal conductivity sensor, including the steps of:

1) coating a helical wire coil with a dense, thin refractory layer first, followed by a relatively loose thick refractory layer to sheathe the whole coil by CVD, PECVD, thermal spraying deposition, or electrophoretic deposition; and

2) fabricating a sensing bead from a coated coil by further depositing a refractory material (e.g. alumina, silica, titania, zirconia, or other refractory metal oxides) by CVD, PECVD, thermal spraying deposition, electrophoretic deposition, or conventional methods; or

3) fabricating a compensating bead from a coated coil by depositing a refractory material (e.g. alumina, silica, titania, zirconia, or other metal oxides) by CVD, PECVD, or conventional methods. The compensating bead is made to differ from the sensing bead in structural and thermal properties such as size, porosity, density, compositions, color, and/or thermal conductivity/capacity. Therefore, the response to a gaseous mixture of the compensating side will differ from that of the sensing side so that a gas concentration can be determined according to the output voltage difference in the Wheatstone bridge.

The thermal conductivity sensor fabricated according to the invention possesses the advantages that 1) it is capable of compensating for environmental humidity effects since the compensating side is not completely sealed or separated from the environmental gas by a reference gas, and 2) a low power thermal conductivity sensor (about 200 mW) can be readily fabricated by using an ultra-fine wire. Since the wire coils for both sensing and compensating elements in this invention are sealed and mechanically stabilized in a structural and protective coating, an ultra-fine wire can be used to build such as a thermal conductivity sensor.

Catalytic bead sensors and thermal conductivity sensors according to the present invention are further illustrated by, but not limited to, the following examples in which CVD is used to deposit a crack-free coating on a coil of wire for use in a sensor. While not specifically exemplified, the other coating methods disclosed herein could be adapted by those of ordinary skill in the art to deposit a crack-free coating on a coil of wire, and especially in consideration of the following references which are incorporated herein by reference for their general disclosures of coating methods:

1) PECVD: U.S. Pat. Nos. 4,394,401, 5,591,494, 5,660,895, 6,220,202 and 6,346,302;

2) electrophoretic deposition: U.S. Pat. Nos. 5,415,748, 5,604,174, 6,071,850 and 6,270,642; and

3) thermal spraying: U.S. Pat. Nos. 4,346,818, 5,389,407, 5,733,662 and 6,258,416.

### EXAMPLE 1

Coat and Sheathe Coils by CVD

In a CVD chamber as illustrated in FIG. 3, coils soldered onto posts of electric headers are cleaned by heating to a temperature in the range of 500-600° C. by application of a suitable voltage. A liquid silane compound in an air carrier flows into the chamber at ambient pressure and room temperature (22.5° C.) at a flow rate controlled in the range of 1-3 CFH by a needle valve and a flow meter, to form a reactant species for deposition. At first, the voltage used to heat the coils is set at a low voltage to achieve a temperature of about 700° C. At this temperature, a low deposition rate is achieved for formation of a thin dense silica coating on the wire of the coils until the coating reaches a thickness of 1-10 μm, and preferably 2-5 μm. Subsequently, the voltage used to heat the coils is adjusted to a higher voltage to achieve a temperature of about 800° C., at which temperature a high deposition rate is obtained for formation of a thick, 20-100 μm and preferably 40-60 μm, relatively loose silica coating on the coils. This layer holds all the turns of the coils together and sheathes the coils, without any shrinkage. The resulting coils have a silica coating, and are used as a starting point in the following examples.

### EXAMPLE 2

Fabrication of Sensing Beads

Based on the resulting coils of EXAMPLE 1, sensing beads are fabricated by using a slurry prepared by adding 0.2 g PdCl₂ and 2.0 g porous alumina powder into 25.0 ml de-ionized water. The slurry is then applied to the coils, followed by passing a current through the coils to heat the coils to 500-700° C. to drive off the water from the slurry, consolidate the alumina deposit and decompose palladium chloride to palladium oxide and palladium metal. Multiple coats and heat are applied until a desired size is obtained.

### EXAMPLE 3

Fabricating Compensating Beads

Based on the resulting coils of EXAMPLE 1, an aqueous or non-aqueous solution containing aluminum nitrate is applied to further coat the sheathed coils, followed by passing a current through the coils to heat the coils to 500-900° C. to decompose aluminum nitrate to alumina. Multiple coats and heat are applied until a desired size is obtained. Then, an aqueous potassium hydroxide solution is applied so that the catalytic activity of alumina is completely suppressed.

### EXAMPLE 4

Fabricating Sensing Beads Partially by CVD

Porous silica is further coated onto the coils from EXAMPLE 1 by CVD through the decomposition of a silane compound until a desired size is reached and a bead is formed.

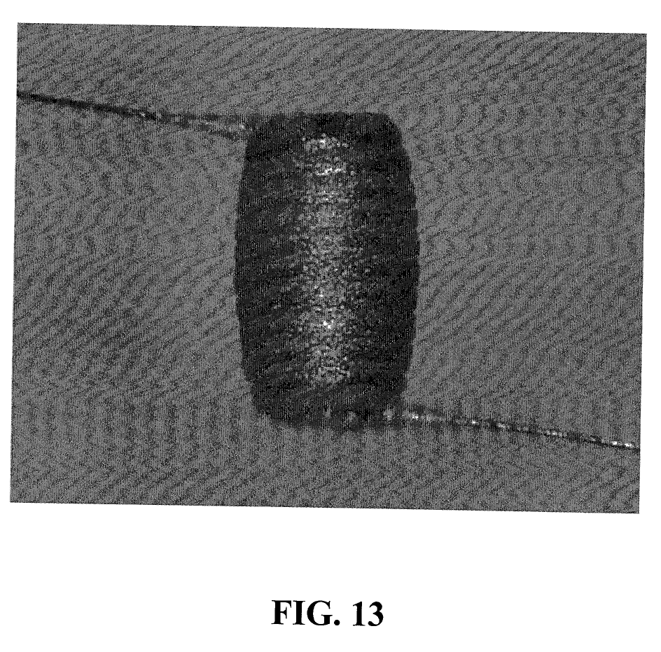

A solution is prepared by adding 0.2 g PdCl₂ to 25.0 ml de-ionized water. This solution is then applied to the bead, followed by passing a current through to heat the coil to 500-700° C. to drive off the water and decompose palladium chloride to palladium oxide and palladium metal. Multiple coats and heat are applied until a desired palladium content is obtained. The sensing bead fabricated in this manner is shown in FIG.13.

### EXAMPLE 5

Fabricating Compensating Beads by CVD

Based on the sheathed coils of EXAMPLE 1, a silane compound is further used to deposit silica on the coils to build up compensating beads. The voltage used to heat the coils is adjusted to achieve a temperature of about 800° C. to obtain a high deposition rate until a suitable bead size is reached.

### EXAMPLE 6

Fabricating Sensing Beads Solely by CVD

The coils of EXAMPLE 1 are first heated in a vacuum reactor chamber to a temperature of 500-600° C. by applying a suitable voltage. Water vapor in the chamber is removed with a vacuum system. Then, a carrier gas, specifically air, is directed over the heated coils, the pressure in the vacuum chamber rising to a predetermined value. Aluminum isopropoxide (Alfa Aesar, Ward Hill, Mass, 99.99%, b.p. 140.5° C./8 mm) in an evaporator is introduced into the carrier gas upstream of the coils to bring the total pressure in the vacuum chamber to a higher value. The coils are then heated to 300-900° C., at which temperature the reactive species decompose to form aluminum oxide on the coils until beads are formed and reach a desired size. The beads are then transferred to a subsequent CVD chamber, where highly dispersed platinum catalyst is deposited onto the surface of alumina in the beads by vaporizing and decomposing a precursor of Pt(acac)₂.

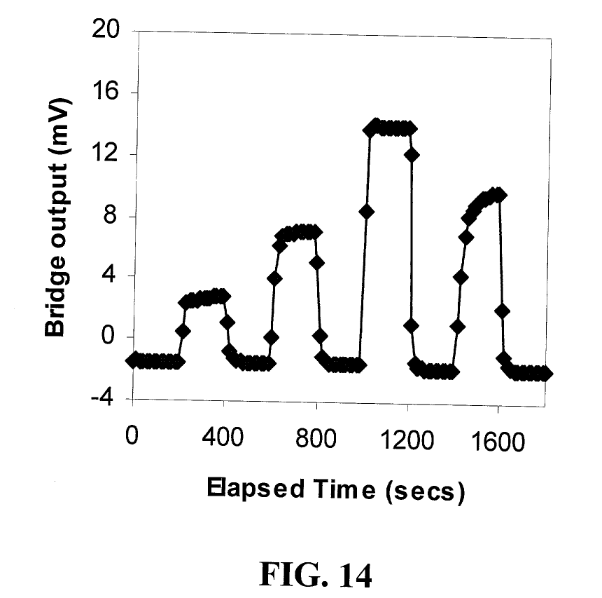

The bridge output of the sensor assembled from the sensing bead in EXAMPLE 4 and the compensating bead in EXAMPLE 5 is shown in FIG. 14, where the sensor is subjected to exposures to zero air, 2.5% methane, zero air, 0.35% pentane, zero air, 0.63% acetylene, zero air, 0.65% acetone, and zero air, respectively. The results indicate that the gas sensor responds to a variety of combustible gases and vapors.

What is claimed is:

1. A method for forming a sensing or compensating bead for a gas sensor, comprising the steps of:
forming a coil of metal wire;
depositing onto the coil of wire by CVD, PECVD, thermal spraying or electrophoretic deposition at least one first layer of an insulating, crack-free refractory coating, to form thereby a coil of coated wire; and
depositing onto the coated wire coil at least one further layer to convert the coated wire coil to a sensing or compensating bead.

2. The method of claim 1, wherein said depositing at least one first layer comprises depositing onto the coil a layer of a refractory material to sheath the coil and stabilize the coil dimensionally.

3. The method of claim 1, wherein said depositing at least one first layer comprises depositing onto the coil of wire at least one first, relatively thin, crack-free refractory coating layer, followed by at least one, relatively thick, second layer of a refractory material to sheath the coil and stabilize the coil dimensionally.

4. The method of claim 1, wherein the coil is formed of platinum or platinum alloy wire.

5. The method of claim 3, wherein the at least one first layer has a thickness of about 1-10 μm.

6. The method of claim 5, wherein the at least one first layer has a thickness of about 2-5 μm.

7. The method of claim 3, wherein the at least one second layer has a thickness of about 20-100 μm.

8. The method of claim 7, wherein the at least one second layer has a thickness of about 40-60 μm.

9. The method of claim 3, wherein the at least one second layer is deposited at a higher temperature than the at least one first layer to increase deposition rate.

10. The method of claim 1, wherein the coating layer comprises at least one refractory material selected from the group consisting of carbides, nitrides and oxides.

11. The method of claim 10, wherein the at least one refractory material is selected from the group consisting of alumina, silica, titania, zirconia, aluminum carbide and silicon nitride.

12. The method of claim 1, wherein the coating layer is deposited from at least one gas phase compound selected from the group consisting of silicon hydrides, silicon tetrachloride, dichlorosilane, methyl trichlorosilane, silicon tetrafluoride, aluminum chloride, aluminum bromide, titanium chloride, zirconium chloride, zirconium bromide, hexamethyldisiloxane, tetramethoxysilane, tetraethoxysilane, diacetoxyditertiarybutoxy silane, octamethyl-cyclotetrasiloxane, tris(2,2,6,6-tetramethyl-3,5-heptanedionato)aluminum, aluminum isopropoxide, trimethyl aluminum, triethyl aluminum, tetraisopropyl titarate, tetrakis-diethylamino titanium, tetrakis-dimethylamino titanium, zirconium tetramethyl heptadionate, bis(cyclopentadienyl)zirconium, zirconium (IV) trifluoroacetylacetonate and zirconium ethoxide.

13. The method of claim 11, wherein the gas phase compound includes an additional reactant selected from the group consisting of oxygen, ozone, carbon dioxide, hydrogen peroxide, nitrous oxide, ammonia, nitrogen, a hydrocarbon gas and mixtures thereof.

14. The method of claim 1, additionally comprising a step of cleaning said coil of wire by heating to a temperature of about 500-800° C. in an oxidizing or inert atmosphere before depositing said coating layer.

15. The method of claim 1, wherein said depositing of said coating layer carried out with at least one gas phase reactant in combination with at least one carrier gas.

16. The method of claim 1, additionally comprising heating the coil after depositing said coating layer to a temperature of about 800-1500° C. to stabilize the deposited layer.

17. The method of claim 1, wherein a sensing bead is fabricated by depositing onto the coated wire coil a slurry comprising at least one catalyst support powder and at least one catalyst precursor, and heating the coil with deposited slurry to decompose the precursor to form a catalyst dispersed on a support surface.

18. The method of claim 17, wherein the at least one catalyst support powder is a porous metal oxide.

19. The method of claim 18, wherein the porous metal oxide is selected from the group consisting of alumina, zirconia, and zirconia stabilized with cerium, lanthanum or yttrium.

20. The method of claim 16, wherein the catalyst precursor is a noble metal salt.

21. The method of claim 20, wherein the noble metal is platinum, palladium or rhodium.

22. The method of claim 17, additionally comprising forming a compensating bead by depositing at least one further layer which is a catalyst poison.

23. The method of claim 22, wherein the at least one further layer is selected from the group consisting of a glass layer, a silica layer, an alkali compound solution and an alkaline earth compound solution.

24. The method of claim 1, wherein the sensing bead is fabricated depositing onto the coated wire coil a catalyst support by CVD, PECVD, thermal spraying or electrophoretic deposition, followed by deposition of a catalyst precursor from a solution, and heating to convert the precursor to a catalyst.

25. The method of claim 24, additionally comprising forming a compensating bead by depositing at least one further layer to inhibit catalytic activity.

26. The method of claim 25, wherein the at least one further layer is selected from the group consisting of a glass layer, a silica layer, an alkali compound solution and an alkaline earth compound solution.

27. The method of claim 1, wherein the sensing bead is fabricated by depositing onto the coated wire coil a catalyst support and a catalyst, sequentially or simultaneously, by CVD, PECVD, thermal spraying or electrophoretic deposition.

28. The method of claim 27, wherein the catalyst support is a porous metal oxide.

29. The method of claim 28, wherein the porous metal oxide is selected from the group consisting of alumina, zirconia, and zirconia stabilized with cerium, lanthanum or yttrium.

30. The method of claim 27, wherein the catalyst is at least one noble metal.

31. The method of claim 30, wherein the noble metal is platinum, palladium or rhodium.

32. The method of claim 31, wherein the noble metal is deposited from a precursor selected from the group consisting of platinum acetylacetonate, platinum dicarbonyl dichloride, platinum hexafluoro-2,4-pentadionate, platinum tetrakis-trifluorophosphine, tris(dibenzylideneacetone)dipalladium, palladium acetate, rhodium acetyl acetonate, rhodium trifluoro-acetyl acetonate and rhodium carbonyl.

33. The method of claim 27, wherein the deposition is simultaneous and the precursor is platinum (0)-1,3-1,1,3,3-tetramethyldisiloxane complex or platinum(0)-2,4,6,8-tetramethyl-2,4,6,8 tetravinyl-cyclotetrasiloxane complex.

34. The method of claim 1, wherein a compensating bead is fabricated by depositing onto the coated wire coil by CVD, PECVD, thermal spraying or electrophoretic deposition at least one material which does not support catalytic combustion of gases.

35. The method of claim 34, wherein the at least one material comprises silica.

36. The method of claim 1, wherein a compensating bead is fabricated by depositing onto said sensing bead by CVD, PECVD, thermal spraying or electrophoretic deposition at least one further layer which is a catalyst poison.

37. The method of claim 1, wherein the wire is hollow.

38. The method of claim 1, wherein the bead is a sensing or compensating bead for a thermal conductivity sensor, and the at least one further layer is a refractory layer deposited by CVD, PECVD, thermal spraying deposition or electrophoretic deposition.

39. The method of claim 1, wherein said depositing takes place by PECVD at a temperature of about 200-800° C.

40. The method of claim 1, wherein said depositing takes place by CVD at a temperature of about 500-1200° C.

41. The method of claim 1, wherein said depositing takes place by electrophoretic deposition at a temperature of about 0-100° C.

42. The method of claim 1, wherein said depositing takes place by thermal spraying at a temperature of about 200-1200° C.

43. The method of claim 1, wherein the metal wire has a diameter of about 7.5 to 50 μm.

44. The method of claim 1, wherein the coil is a generally helical coil of diameter about 0.127 to 0.763 mm.

45. The method of claim 1, wherein the coil has a length of about 0.203 to 2.54 mm.

46. The method of claim 45, wherein the coil has a length of about 0.305 to 0.457 mm.

47. The method of claim 1, wherein a compensating bead is fabricated by depositing onto the coated wire coil at least one refractory material from a slurry or solution, and at least one further layer which is a catalyst poison.

48. The method of claim 47, wherein the at least one refractory material is selected from the group consisting of alumina, silica, titania, zirconia and an alumina-binder mixture.

49. The method of claim 47, wherein the at least one further layer is selected from the group consisting of glass, silica, an alkali solution and an alkaline earth solution.

50. The method of claim 1, wherein a compensating bead is fabricated by depositing onto the coated wire coil at least one refractory material by CVD, PECVD, thermal spraying deposition or electrophoretic deposition, and at least one further layer which is a catalyst poison.

51. The method of claim 50, wherein the at least one refractory material is selected from the group consisting of alumina, silica, titania, and zirconia.

52. The method of claim 50, wherein the at least one further layer is selected from the group consisting of glass, silica, an alkali solution and an alkaline earth solution.
